(19) United States
(12) Patent Application Publication
(10) Pub. No.: US 2006/0071300 A1
(43) Pub. Date: Apr. 6, 2006

(54) Dielectric material having carborane derivatives

(76) Inventors: Michael G. Haverty, Mountain View, CA (US); Tim T. Chen, Phoenix, AZ (US); Sadasivan Shankar, Cupertino, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/957,231

(22) Filed: Sep. 30, 2004

(51) Int. Cl. H01L 23/58

(52) U.S. Cl. 257/632

(57) ABSTRACT

Numerous embodiments of an apparatus and method of a dielectric material having a low dielectric constant and good mechanical strength are described. In one embodiment a dielectric material having multiple porous regions is disposed over a substrate. A caged structure is bridged within the plurality of pores. In one particular embodiment, the caged structure may be carborane or a carborane derivative.

### FIELD

Embodiments of the present invention relate to the field of semiconductor manufacturing, and, more specifically, to a method of forming a low-dielectric constant material.

### BACKGROUND

In the fabrication of semiconductor devices, substrates are provided and processed to form semiconductor devices. For example, in the fabrication of microchips, the initial wafer serves as a substrate to support features such as transistors and conductive metal lines. Processing generally involves depositing and modifying layers of material on the initial wafer for various purposes. For example, an interlayer dielectric (ILD) may be deposited and patterned to form and electrically isolate conductive metal lines, or traces. Reducing capacitance between the conductive lines is an important goal in the formation of ILD's. Capacitance in the wiring may be reduced by using an electrically insulating material with a lower dielectric constant (k). As semiconductor devices and device features decrease in size, the distance between such conductive lines correspondingly decreases. However, as the distance between lines decreases, the capacitance increases. Unfortunately, as capacitance increases so does signal transmission time, while high frequency capability may be reduced. Other problems such as increased cross-talk can also occur as the capacitance between lines increases.

The dielectric constant is different for different materials. For example, where the dielectric is of a vacuum or air, the dielectric constant (k) is about equal to 1, having no effect on capacitance. However, most ILD materials have a dielectric constant significantly greater than 1. For example, silicon dioxide, a common ILD material, has a dielectric constant generally exceeding 4. Due to the decreasing size of semiconductor features, which decreases the distance between lines, efforts have recently been made to reduce the dielectric constant of the ILD as a means by which to reduce capacitance.

Low dielectric constant materials (i.e., “low k” materials), such as carbon doped oxides (CDO's) have been used to form the ILD, thereby reducing capacitance. Unfortunately, such materials are typically weak in mechanical strength, particularly as the dielectric constant value gets lower. One reason low k materials have poor mechanical strength is that they are typically porous structures, reflecting a low Young's Modulus. Therefore these materials often deteriorate when exposed to subsequent semiconductor processing. As such, materials with higher dielectric constant (k) values are currently used, or alternative manufacturing processes are used to reduce the mechanical stress on the lower k ILD materials.

### BRIEF DESCRIPTION OF THE DRAWINGS

Embodiments of the present invention are illustrated by way of example, and not limitation, in the figures of the accompanying drawings in which:

FIG. 1 illustrates a cross-sectional view of a partially processed substrate having a porous dielectric layer in one embodiment of the present invention.

FIG. 2 illustrates a silicon dioxide framework having a porous region.

FIG. 3 illustrates the silicon dioxide framework of FIG. 2 having a carborane structure forming a bridge within the porous region.

FIG. 4 illustrates one embodiment of a carborane structure.

FIG. 5 illustrates one embodiment of a carborane structure having carbon elements substituted for boron elements.

FIG. 6 illustrates one embodiment of a carborane structure coupled to silicon chains.

FIG. 7 illustrates a block diagram of one embodiment of forming a dielectric layer over a substrate.

### DETAILED DESCRIPTION

In the following description, numerous specific details are set forth such as examples of specific materials or components in order to provide a thorough understanding of embodiments of the present invention. It will be apparent, however, to one skilled in the art that these specific details need not be employed to practice embodiments of the present invention. In other instances, well known components, methods, semiconductor equipment and processes have not been described in detail in order to avoid unnecessarily obscuring embodiments of the present invention.

The terms “on,” “above,” “below,” “between,” and “adjacent” as used herein refer to a relative position of one layer or element with respect to other layers or elements. As such, a first element disposed on, above or below another element may be directly in contact with the first element or may have one or more intervening elements. Moreover, one element disposed next to or adjacent another element may be directly in contact with the first element or may have one or more intervening elements.

Any reference in the specification to “one embodiment” or “an embodiment” means that a particular feature, structure, or characteristic described in connection with the embodiment is included in at least one embodiment of the claimed subject matter. The appearances of the phrase, “in one embodiment” in various places in the specification are not necessarily all referring to the same embodiment.

Embodiments of material having a low dielectric constant and a method to form a material having a low dielectric constant are described. In one embodiment of the present invention, carborane structures form a bridge within porous regions of dielectric layer that results in the dielectric layer having a low dielectric constant with good mechanical strength.

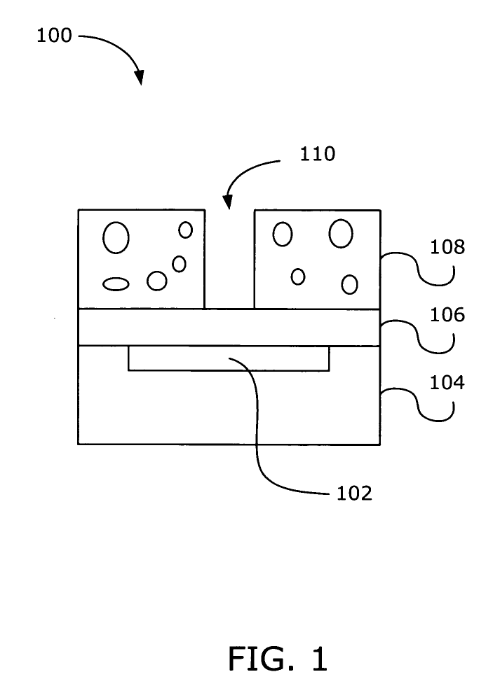

FIG. 1 illustrates a cross-sectional view of a partially processed substrate 100 in one embodiment of the present invention. Substrate 100 may be a wafer upon which other manufacturing and processing operations may be performed so as to form various electrical components, including but limited to, transistors, as well as conductive interconnections. Substrate 100 includes a low dielectric constant material which that exhibits good mechanical strength. Measurements of mechanical strength may include Young's modulus of elasticity, shear strength, and fracture toughness. An underlying conductor 102, connected to a device, is formed in a dielectric material 104 that is part of substrate 100. The dielectric material 104 may be covered with an etch stop layer 106. In one embodiment, the etch stop layer 106 may have a thickness selected from a range of about 200 to about 1,500 Angstroms. The etch stop layer 106 is thick enough to prevent breakthrough when an opening, such as a via opening 110, is formed later in an overlying dielectric material, such as an interlayer dielectric (ILD) 108. The formation of the via opening 110 may involve an etch of the ILD 108, as well as various precleans and postcleans associated with the etch. Materials that may be used for the etch stop layer 100 include Silicon Nitride (Si₃N₄) which has a k value of about 6.5 and Silicon Carbide (SiC) which has a k value of about 4.5 to about 5.5. The k value may be determined by measuring capacitance on a parallel-plate electrical structure.

A porous ILD 108 may be formed over the etch top layer 106. The ILD 108 may have a thickness selected from a range of about 0.1 to about 2.0 microns (μ). A dielectric material may be considered to be low-k if its k value is lower than the k value of undoped silicon dioxide (SiO₂) which is about 3.9 to about 4.5. The ILD 108 may be formed in various ways, such as by using a chemical vapor deposition (CVD) process. In one embodiment, the ILD 108 may be formed using a plasma-enhanced CVD (PECVD) process. Process conditions may include a power of about 300-2,500 Watts (W), a pressure of about 500-1,000 Pascals (Pa), and a gas flow rate of about 300-1,000 standard cubic feet per minute (scfm). In one embodiment, ILD 108 may be formed from any one of a plurality of known dielectric materials.

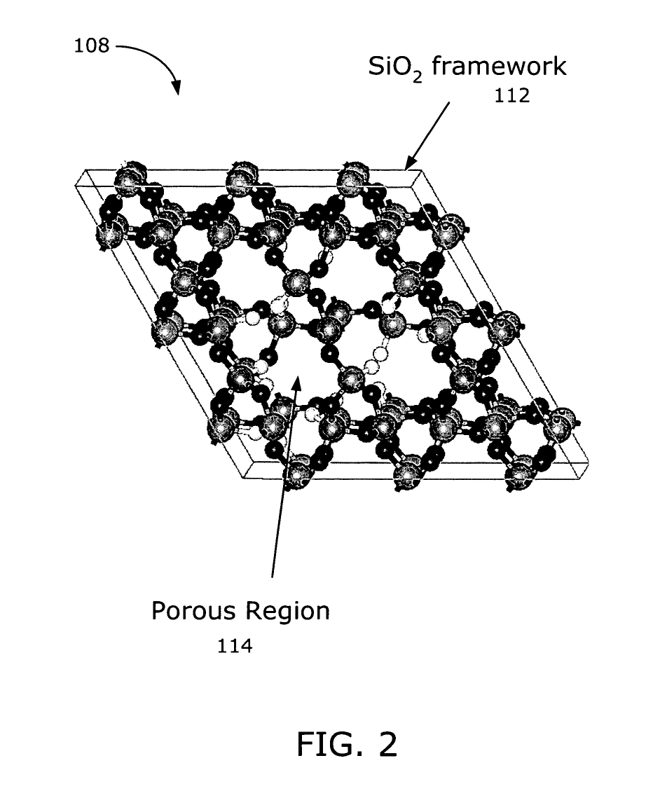

Pores may be created in the ILD 108 to lower the k value of the ILD 108. FIG. 2 illustrates one embodiment of the present invention in which at least one porous region 114 is formed within a SiO₂ framework 112 that makes up ILD 108. ILD 108 is shown three-dimensionally and isolated from other elements of FIG. 1 (e.g., conductor 102). For clarity of description, only one porous region is illustrated, although it may be appreciated that multiple porous regions may be formed within SiO₂ framework 112. The k value of the ILD 108 may then depend on the k value of the bulk material forming the ILD 108 and the k value of the pores or any material filling the pores, weighted by the total porosity of the ILD 108. The mechanical strength of the ILD 108 depends on the mechanical strength of the bulk material forming the ILD 108. If the ILD 108 is porous, the mechanical strength of the ILD 108 also depends on the total porosity as well as the distribution of pore sizes and shapes. For a particular value of total porosity, an ILD 108 with larger pore sizes may have greater mechanical strength than an ILD 108 with smaller pore sizes. In one embodiment, pores may be formed in ILD 108 by including a pore forming material, or porogen, when forming ILD 108. In another embodiment, pores may be formed by modifying the processing conditions concurrently or subsequently to the formation of ILD 110.

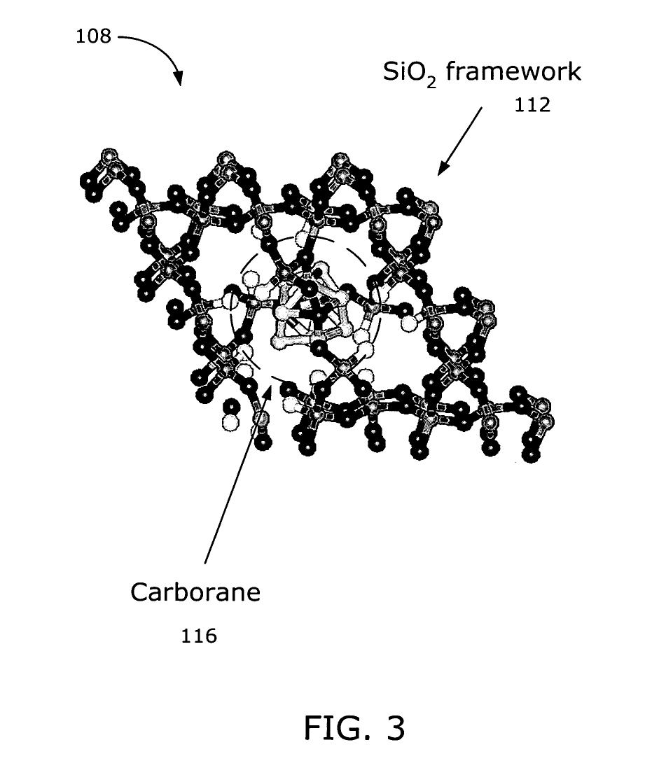

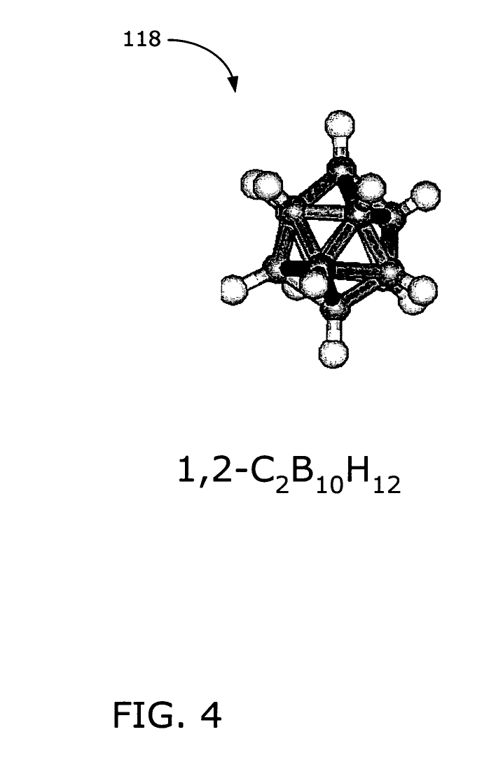

FIG. 3 illustrates ILD 108 having a caged structure that bridges porous region 114 of SiO₂ framework 112. In one embodiment of the present invention, the caged structure may be carborane 116. Carboranes are a broad class of boron and carbon-containing structures which naturally form closed icosahedral shell structures. In one embodiment, the insertion of a carborane bridge into portion region 114 may result in a reduction in the bulk modulus of about 10% to about 20% relative to a SiO₂ framework 112 having no porous regions. FIG. 4 illustrates a three-dimensional structure 118 of B-carborane-2C (1,2-C₂B₁₀H₁₂) in its naturally caged formation. The boron atoms form bonds to 3 or more atom through on shared electron pair which allows for the formation of the 12-vertex B-carborane-2C structure. The carbon atoms in the caged structure offer areas for various silicon and carbon chain structures to be attached (e.g., as precursors of CVD and plasma processing). In one embodiment, B-carborane-2C forms a caged structure that is about 3 to about 6 Angstroms in diameter. Because of their naturally caged structure, carboranes introduce porosity into the dielectric material framework (e.g., SiO₂ framework 112) because of its robust structure by providing atomic bonds through which transfer of mechanical forces around the walls of the porous region (e.g., porous region 114), thereby increasing the Young's Modulus relative to SiO₂ framework 112 having no bridging structures disposed within the porous region. Moreover, the caged structure of carborane, when disposed within a porous region, maintains a certain level of porosity to lower the dielectric constant value.

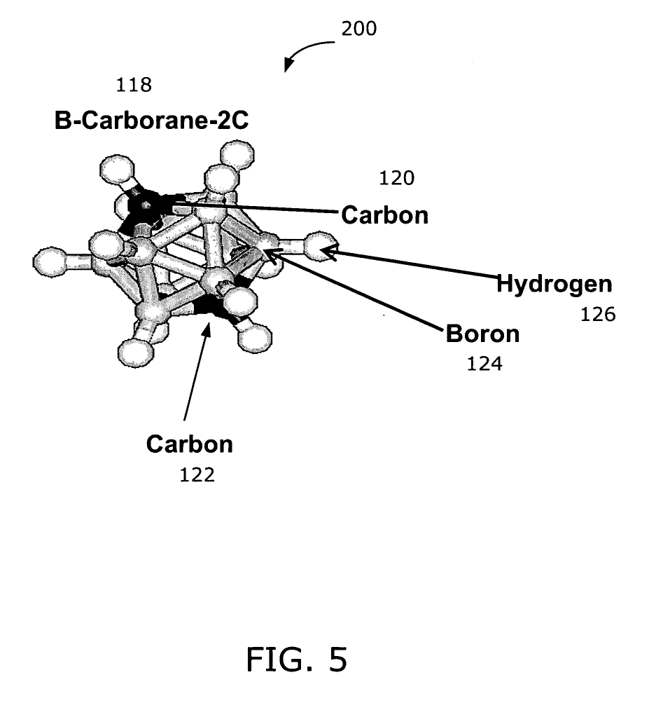

In one embodiment, the chemical make-up of carborane may be changed (e.g., adding chained molecules or substituting one or atoms), while still maintaining the caged formation, to reduce the dielectric constant of ILD 108. In one embodiment, carbon atoms may be substituted into the carborane cage structure to reduce the dielectric constant. In another embodiment, silicon chains may be (e.g., Si₃H₇) may be attached to carbon atoms to reduce the dielectric constant. In yet another embodiment, carbon chains (e.g., C₃H₇) may be attached to carbon atoms to reduce the dielectric constant. FIG. 5 illustrates one embodiment of B-carborane-2C 118 which has been modified by the substitution of 2 carbon groups 120 and 122 for boron atoms (as distinguished from boron 124 and hydrogen 126 atoms). The carbon substituted carborane structure 200 may be disposed within porous region 114 of SiO₂ framework 112 to form a bridge that extends across porous region 114. In one embodiment, the increase in the percentage of carbon atoms in the carborane structure may result in a dielectric constant (k) between about 2.5 to about 3.8 for ILD 108. In one embodiment, the range of dielectric constant (k) values refers to the electronic portion of the dielectric constant and separate from the ionic portion of the dielectric constant (e.g., the total dielectric constant value is equal to the sum of the electronic portion and the ionic portion). In certain types of dielectric materials, the electronic portion may be an important element. The range of dielectric constant (k) values may, in one embodiment, correspond to ILD 108 having a film density ranging from about 1.0 to about 1.5 grams/cm³.

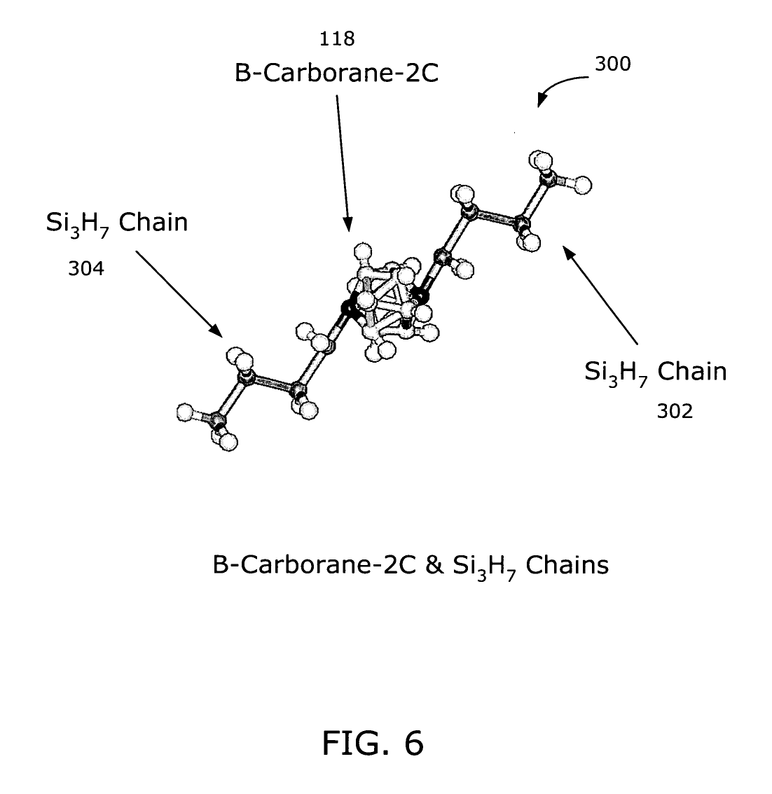

FIG. 6 illustrates one embodiment of a carborane structure 300 which has been modified by the addition of two silicon chains (Si₃H₇), 302 and 304 on either side of B-carborane-2C 118. Carborane structure 300 forms a bridge across porous region 114 of SiO₂ framework 112. In one embodiment, the increase in the percentage of silicon chains in the carborane may result in a dielectric constant (k) between about 2.4 to about 3.4 for ILD 108. In one embodiment, the range of dielectric constant (k) values refers to the electronic portion of the dielectric constant and separate from the ionic portion of the dielectric constant. The range of dielectric constant (k) values may, in one embodiment, correspond to ILD 108 having a film density ranging from about 1.0 to about 1.5 grams/cm³. It may be appreciated that any number of silicon chains may be coupled to B-carborane-2C 118 to form a bridge across porous region 114. In one particular embodiment of the present invention, between about 2 to about 4 silicon chains may be coupled to B-carborane-2C 118.

In an alternative embodiment, carborane structure 300 may modified by the addition of two carbon chains (C₃H₇, not shown) on either side of B-carborane-2C 118. The carbon chain modified carborane structure forms a bridge across porous region 114 of SiO₂ framework 112. In one embodiment, the increase in the percentage of carbon chains in the carborane structure may result in a dielectric constant (k) between about 1.8 to about 2.5 for ILD 108. In one embodiment, the range of dielectric constant (k) values refers to the electronic portion of the dielectric constant and separate from the ionic portion of the dielectric constant. The range of dielectric constant (k) values may, in one embodiment, correspond to ILD 108 having a film density ranging from about 1.0 to about 1.5 grams/cm³. It may be appreciated that any number of carbon chains may be coupled to B-carborane-2C 118 to form a bridge across porous region 114. In one particular embodiment of the present invention, between about 2 to about 4 silicon chains may be coupled to B-carborane-2C 118. In yet another alternative embodiment of the present invention, a combination of silicon chains (Si₃H₇) and carbon chains (C₃H₇) may be coupled to the structure of B-carborane-2C 118. For example, a carbon chain and a silicon chain may be coupled to opposite sides of B-carborane-2C 118 to form a bridge across porous region 114. It may be appreciated that any number of carbon and silicon chains may be coupled to B-carborane-2C 118 to form a bridge across porous region 114.

In alternative embodiment, a ring structure such as benzene (C₆H₆) may be used to bridge porous region 114. A benzene ring has low polarization characteristics similar to carborane, resulting in a lower dielectric constant. The relatively large ring size of benzene allows it to exhibit similar mechanical properties as silicon and carbon chain derivatives of carborane, as described above for bridging across porous regions. In yet another embodiment, a Fullerene molecule, also referred to as “Buckyball” or “Buckminsterfullerene” may be used to bridge porous region 114. The Fullerene molecule has a structure of sixty carbon atoms arranged in a sphere similar to the vertices of a soccer ball. The spherical structure of the Fullerene molecule allows it to exhibit similar mechanical properties as silicon and carbon chain derivatives of carborane.

The various linear, circular, and caged structures described herein (e.g., carborane, carborane derivatives, benzene, Fullerene) may included into the framework (i.e., bridging porous regions) of a dielectric material or layer by direct chemical vapor deposition. In an alternative embodiment, downstream plasma-enhanced chemical vapor deposition or physical vapor deposition may be used. Other deposition techniques known in the art may be used.

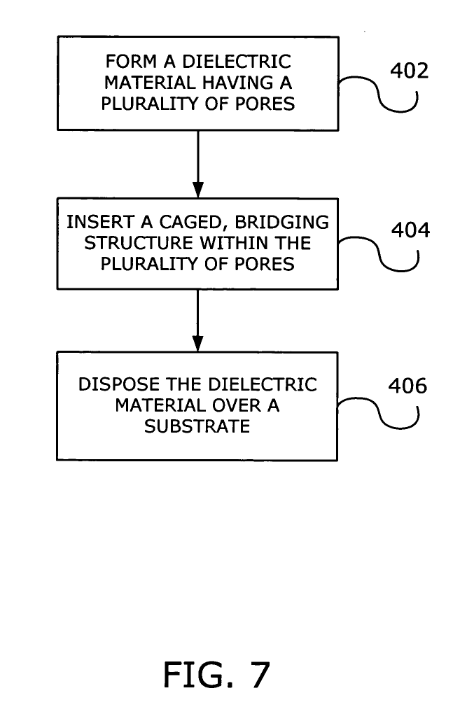

FIG. 7 illustrates is a block diagram of one method for forming a dielectric material having a low dielectric constant while retaining good mechanical strength. A dielectric material is formed is formed having a plurality of pores, block 402. The dielectric material may be an ILD layer (e.g., ILD 118) used in semiconductor device manufacturing. In one embodiment, the ILD layer may include a SiO₂ framework (e.g., SiO₂ framework 112) having a plurality of pore regions (e.g., porous region 114) formed therein. A caged structure may be inserted into the porous region to form a bridge within the porous region, block 404. In one embodiment, the caged structure may be carborane or a carborane derivative. For example, the bridge may be formed by B-carborane-2C (e.g., B-carborane-2C 118) or by a B-carborane-2C structure coupled by silicon or carbon chains (e.g., structures 200, 300). Alternatively, a benzene ring may be used to bridge the porous region. The insertion of a bridging, caged structure into the porous region of dielectric layer introduces porosity into the framework while providing a robust framework to withstand various processing conditions. The dielectric material may then be disposed or deposited over a substrate, block 406, or other elements of a semiconductor device (e.g., etch stop layer 106). In one embodiment, the dielectric layer, having porous regions with bridging structures, may be formed by a spin-coating process that deposits the dielectric material onto the substrate. In an alternative embodiment, the dielectric layer may be formed by a chemical vapor deposition (CVD) process in which a dielectric material is first deposited on a substrate, followed by the formation pore regions within the dielectric layer, and the insertion of caged, bridging structures within the pore regions. In one embodiment, the carborane/carborane-derivative dielectric material has a dielectric constant (k) between about 1.8 to about 3.8.

In the foregoing specification, the invention is described with reference to specific embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. An apparatus, comprising:
a substrate;
a dielectric material disposed over the substrate, the dielectric material having a plurality of porous regions; and
a caged structure bridged within the plurality of porous regions.

2. The apparatus of claim 1, wherein the caged structure comprises a carborane bridge.

3. The apparatus of claim 2, wherein the carborane bridge comprises a carbon chain.

4. The apparatus of claim 2, wherein the carborane bridge comprises a silicon chain.

5. The apparatus of claim 2, wherein the carborane bridge includes carbon elements substituted for the boron elements.

6. The apparatus of claim 2, wherein the dielectric material comprises a silicon dioxide framework.

7. The apparatus of claim 1, wherein the caged structure comprises a benzene bridge.

8. The apparatus of claim 1, wherein the dielectric material has a dielectric constant value between about 1.8 to about 3.8 and a density of about 1.0 to about 1.5 g/cm².

9. A semiconductor device, comprising:
a substrate;
a silicon dioxide layer disposed over the substrate, the silicon dioxide layer having at least one pore formed therein; and
a carborane bridge to extend across the at least one pore.

10. The semiconductor device of claim 9, wherein the carborane bridge further comprises at least one carbon chain.

11. The semiconductor device of claim 9, wherein the carborane bridge further comprises at least one silicon chain.

12. The semiconductor device of claim 9, wherein the silicon dioxide layer forms a dielectric material.

13. The semiconductor device of claim 12, wherein the silicon dioxide layer has a dielectric constant value between about 1.8 to about 3.8 and a density of about 1.0 to about 1.5 g/cm².

14. The semiconductor device of claim 9, wherein the carborane bridge further comprises between about two to about four carbon chains.

15. The semiconductor device of claim 9, wherein the carborane bridge further comprises between about two to about four silicon chains.

16. The semiconductor device of claim 10, wherein the silicon dioxide layer has a dielectric constant value between about 1.8 to about 2.5 and a density of about 1.0 to about 1.5 g/cm².

17. The semiconductor device of claim 11, wherein the silicon dioxide layer has a dielectric constant value between about 2.4 to about 3.4 and a density of about 1.0 to about 1.5 g/cm².

18. A method, comprising:
forming a dielectric material having a plurality of pores;
inserting a caged, bridging structure within the plurality of pores; and
disposing the dielectric material over a substrate.

19. The method of claim 18, wherein inserting further comprises coupling a carborane bridge within the plurality of pores.

20. The method of claim 19, wherein inserting further comprises attaching a carbon chain to the carborane bridge.

21. The method of claim 19, wherein inserting further comprises attaching a silicon chain to the carborane bridge.

22. The method of claim 19, wherein inserting further comprises substituting boron elements with carbon elements in the carborane bridge.

23. The method of claim 18, wherein inserting further comprises coupling a benzene bridge within the plurality of pores.
